(19) United States
(12) Patent Application Publication
(10) Pub. No.: US 2023/0123307 A1
(43) Pub. Date: Apr. 20, 2023

(54) ELECTRONIC DEVICE HAVING CHEMICALLY COATED BUMP BONDS

(71) Applicant: TEXAS INSTRUMENTS INCORPORATED, Dallas, TX (US)

(72) Inventor: Nazila Dadvand, Sunnyvale (CA)

(21) Appl. No.: 17/504,182

(22) Filed: Oct. 18, 2021

(51) Int. Cl. H01L 23/00

(52) U.S. Cl. CPC H01L 24/11; H01L 24/13; H01L 2224/11019; H01L 2224/1182; H01L 2224/11831; H01L 2224/1181; H01L 2224/11622; H01L 2224/13147; H01L 2224/13611; H01L 2224/13664; H01L 2224/13582

(57) ABSTRACT

A system and method for etching a die in a tin (Sn) electrolyte. The die includes a silicon wafer and a diffusion barrier disposed on the silicon wafer. A copper seed layer disposed on the diffusion barrier and at least one copper bump bond is disposed on a portion of the copper seed layer. A tin layer is disposed on side walls of the at least one copper bump bond. The tin layer inhibits etching of the side walls of the at least one copper bump bond during an etching process to the copper seed layer to remove exposed portions of the copper seed layer.

### TECHNICAL FIELD

The present disclosure relates to an electronic device having chemically coated bump bonds.

### BACKGROUND

During a formation of a die in an integrated circuit (IC) package, a diffusion barrier layer is deposited on a wafer (e.g., silicon) and a thin copper seed layer is deposited on the diffusion barrier layer. The thin copper seed layer allows the plating of the larger features. For example, a copper bump bond is deposited via electroplating on a portion or portions of the copper seed layer. Additional layers, (e.g., nickel, palladium) may be deposited via electroplating on the copper bump bonds. Once the electroplating processes are complete, exposed portions (portions where the copper bump bonds are not deposited) of the copper seed layer are removed via etching. During removal of the exposed portions of the copper seed layer, however, portions of the copper bump bond are also removed, which are not meant to be removed. In addition, the copper seed layer etches at a faster rate than the copper bump bonds. The difference in etch rates causes the copper bump bond to etch at a slower rate, which etches a lower portion of the copper bump bond thereby forming an overhang on an upper portion of the copper bump bond.

### SUMMARY

In described examples, a method includes providing an array of electronic devices comprising a wafer where each of the electronic devices includes a copper seed layer disposed on the wafer and at least one copper bump bond disposed on a portion of the copper seed layer. The method further includes immersing the array of electronic devices in a tin electrolyte to chemically dissolve an exposed portion of the copper seed layer in the tin electrolyte and to chemically displace electrons from side walls of the at least one copper bump bond. The displaced electrons combine with tin ions in the tin electrolyte to form a layer of tin on the sidewalls of the at least one copper bump bond.

In another described example, a method includes providing an array of electronic devices comprising a silicon wafer where each of the electronic devices includes a titanium-tungsten diffusion barrier disposed on the silicon wafer, a copper seed layer disposed on the titanium-tungsten diffusion barrier, and copper bump bonds disposed on a portion of the copper seed layer. The method further includes immersing the array of electronic devices for no more than ten minutes in a tin electrolyte to chemically dissolve an exposed portion of the copper seed layer in the tin electrolyte and to chemically displace electrons from side walls of the copper bump bonds and rinsing the array of electronic devices with water. The electrons combine with tin ions in the tin electrolyte to form a layer of tin on the sidewalls of the copper bump bonds.

In another described example, die includes a silicon wafer and a diffusion barrier disposed on the silicon wafer. A copper seed layer disposed on the diffusion barrier and at least one copper bump bond is disposed on a portion of the copper seed layer. A tin layer is disposed on side walls of the at least one copper bump bond. The tin layer inhibits etching of the side walls of the at least one copper bump bond during an etching process to the copper seed layer to remove exposed portions of the copper seed layer.

### BRIEF DESCRIPTION OF THE DRAWINGS

FIG. 1 is an example of a die having that includes bump bonds having tin coated sidewalls.

FIG. 2 is a cross section view of a section of a die illustrating etched sidewalls of copper bump bonds.

FIG. 3 is a schematic cross-sectional view of a wafer of the die of FIG. 1 in early stages of fabrication.

FIG. 4 is a schematic cross-sectional view of the die of FIG. 3 after undergoing a deposition of a diffusion barrier layer deposited on the wafer.

FIG. 5 is a schematic cross-sectional view of the die of FIG. 4 after undergoing a deposition of a seed layer on the diffusion barrier layer.

FIG. 6 is a schematic cross-sectional view of the die of FIG. 5 after undergoing a deposition of a photoresist layer on the seed layer.

FIG. 7 is a schematic cross-sectional view of the die of FIG. 6 after undergoing an etch process to the photoresist layer to form openings in the photoresist layer.

FIG. 8 is a schematic cross-sectional view of the die of FIG. 7 after undergoing an electroplating process to deposit bump bonds in the openings of the photoresist layer.

FIG. 9 is a schematic cross-sectional view of the die of FIG. 8 after undergoing an electroplating process to deposit a first metal plating layer on the bump bonds.

FIG. 10 is a schematic cross-sectional view of the die of FIG. 9 after undergoing an electroplating process to deposit a second metal plating layer on the first metal plating layer.

FIG. 11 is a schematic cross-sectional view of the die of FIG. 10 after undergoing an etch process to remove the remaining photoresist layer.

FIG. 12 is a schematic cross-sectional view of the die of FIG. 11 after undergoing an etch process to remove exposed portions of the seed layer.

FIG. 13 is a schematic cross-sectional view of the die of FIG. 12 after undergoing an etch process to remove exposed portions of the diffusion barrier layer.

### DETAILED DESCRIPTION

Disclosed herein is a system and method of fabricating an electronic device (e.g., die) for an integrated circuit (IC) where the electronic device includes electrically conductive mechanical interconnects (e.g., copper bump bonds) that include chemically coated sidewalls to inhibit corrosion to the mechanical interconnects during a chemical etching process. During the chemical etching process, an exchange chemical reaction occurs where a thin metal (e.g., tin) layer replaces a thin layer on the sidewalls of the mechanical interconnect. The exchange chemical reaction inhibits undesired etching to the mechanical interconnect thereby preserving a width of the mechanical interconnect. As a result, the preserved width of the mechanical interconnect increases the number of available electrical connections under the mechanical interconnect, which increases the number of features (e.g., electrical circuits) and current in the electronic device thereby enhancing the performance of the electronic device.

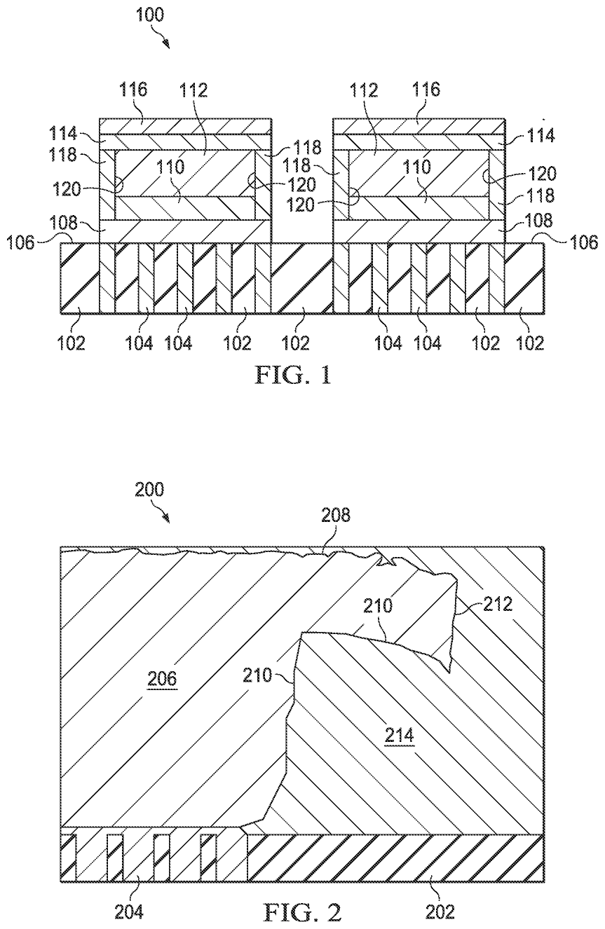

FIG. 1 is an example electronic device (e.g., die) 100 comprised of a wafer (e.g., silicon wafer) 102 having vias 104 defined therein and a generally top planar surface 106. The electronic device 100 further comprises a diffusion barrier layer (e.g., titanium-tungsten) 108 disposed on one or more portions of the top planar surface 106 of the wafer 102 and a seed layer (e.g., copper seed layer) 110 disposed on the diffusion barrier layer 108. An electrically conductive mechanical interconnect (e.g., copper bump bonds) 112 is disposed on the seed layer 110, and first and second metal plating layers (e.g., nickel and palladium) 114, 116 are disposed on the mechanical interconnect 112. A thin (e.g., 0.2-0.3 μm) metal (e.g., tin) layer 118 is deposited on sidewalls 120 of the mechanical interconnect 112 during an etching process. The thin metal layer 118 extends from the first plating layer 114 down to the diffusion barrier layer 108. Thus, the thin metal layer 118 is also deposited on sides of the seed layer 110. As previously mentioned, the thin metal layer inhibits undesired etching to the sidewalls 120 of the mechanical interconnect 112 as illustrated in FIG. 2.

FIG. 2 is a close-up, cross-section view of a partial section of a die 200 that does not include the thin tin metal layer illustrated in FIG. 1. The die 200 includes a silicon wafer 202 having vias 204 defined therein. A copper bump bond 206 is disposed on the silicon wafer 202 and one or more metal layers 208 are electroplated to a top surface of the copper bump bond 206. As illustrated in FIG. 2, during the etching process to etch exposed portions (portions where the copper bump bond is not deposited) of the seed layer, portions of the copper bump bond 206 are partially etched or removed, which are not meant to be removed, as defined by the generally vertical and horizontal etch walls 210. As previously mentioned, the copper seed layer etches at a faster rate than the copper bump bond 206.

The difference in etch rates is due to galvanic corrosion of the copper seed layer on the diffusion barrier layer (e.g., titanium-tungsten). Since the copper seed layer is in direct contact to a noble layer, for example titanium-tungsten, the copper seed layer etches away faster than the copper bump bond resulting in an undercut in a lower portion of the copper bump bond 206. Specifically, the difference in etch rates causes a lower portion of the copper bump bond 206 to etch away thereby forming an overhang 212 on an upper portion of the copper bump bond 206 and a void or undercut 214 below the overhang 212. The undesired removal of the lower portion of the copper bump bond 206 reduces the width of the copper bump bond 206, which decreases the number of available vias and consequently the number of features (e.g., electrical devices, electrical circuits, etc.) that can be added to the die 206.

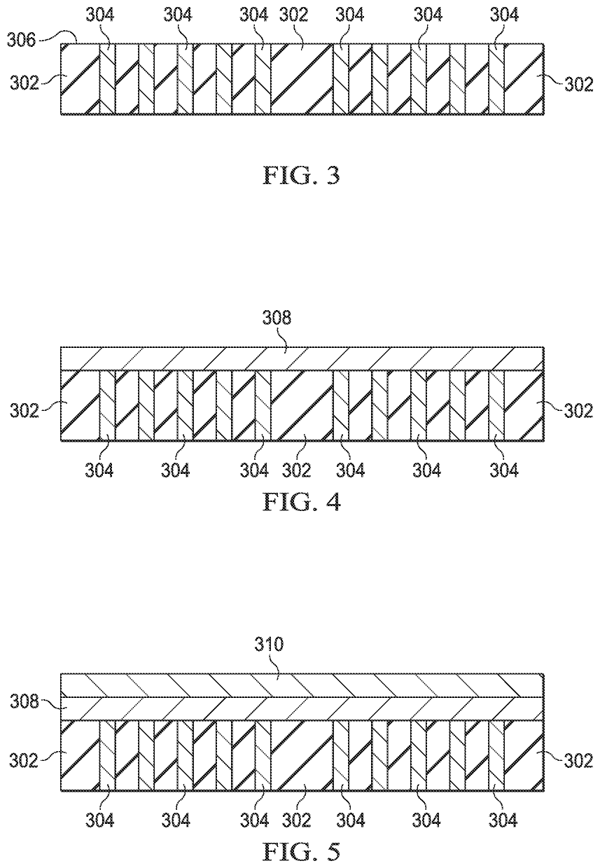

FIGS. 3-13 illustrate a fabricating process of an electronic device 300 in connection with the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 3-13 is an example method illustrating the example configuration of FIG. 1, other methods and configurations are possible.

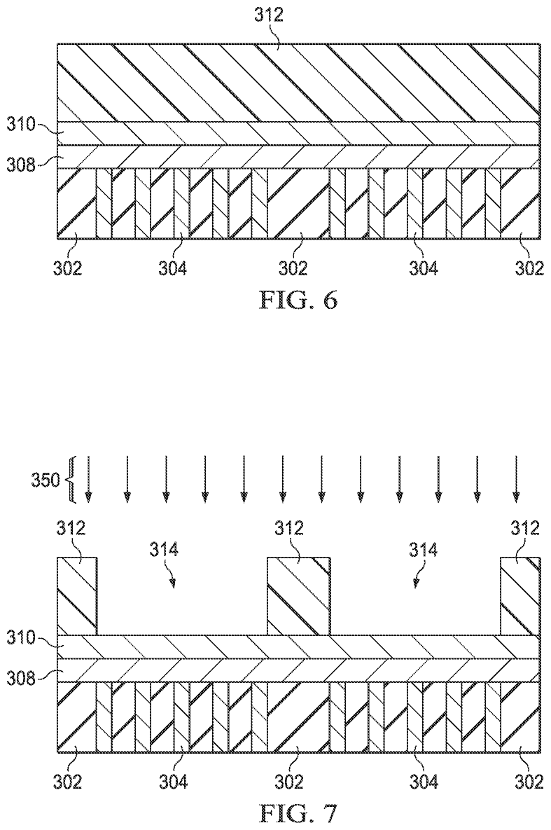

Referring to FIG. 3, the fabricating process begins with a wafer (e.g., silicon) 302 that includes vias 304 and a top planar surface 306. The electronic device 300 may be part of an array of electronic devices provided on a wafer that undergoes a singulation process after the electronic devices are fabricated. A diffusion barrier layer (e.g., titanium-tungsten) 308 is deposited on the top planar surface 306 of the wafer 302 via a sputtering process or other deposition process, see FIG. 4. In FIG. 5, a seed layer (e.g., copper seed layer) 310 is deposited on the diffusion barrier layer 308 via a sputtering process or other deposition process. A photoresist material layer 312 is deposited on a surface of the seed layer 310, see FIG. 6. The photoresist material layer 312 is patterned and developed to expose openings 314 in the photoresist material layer 312, thereby exposing the seed layer 310 within the openings 314, as illustrated in FIG. 7. The photoresist material layer can have a thickness that varies in correspondence with the wavelength of radiation used to pattern the photoresist material layer. The photoresist material layer 312 may be formed over the seed layer 310 via spin-coating or spin casting deposition techniques, selectively irradiated (e.g., via deep ultraviolet (DUV) irradiation) 350 and developed to form the openings 314.

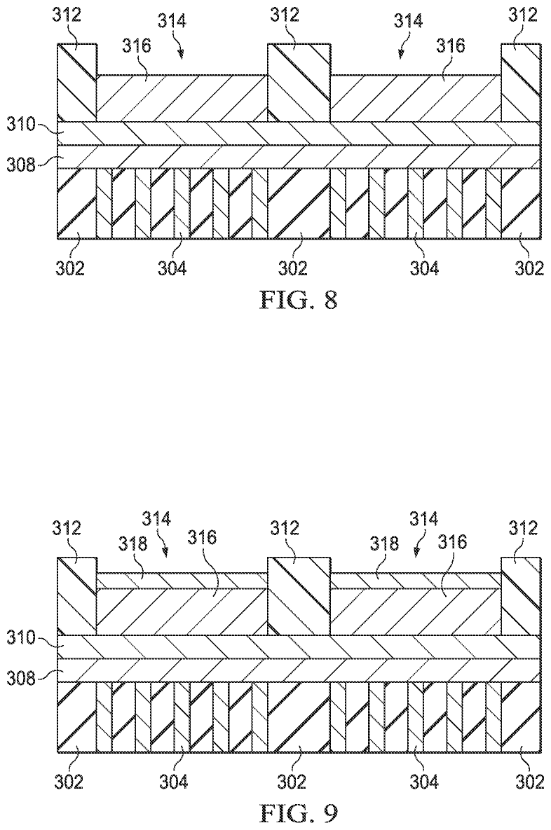

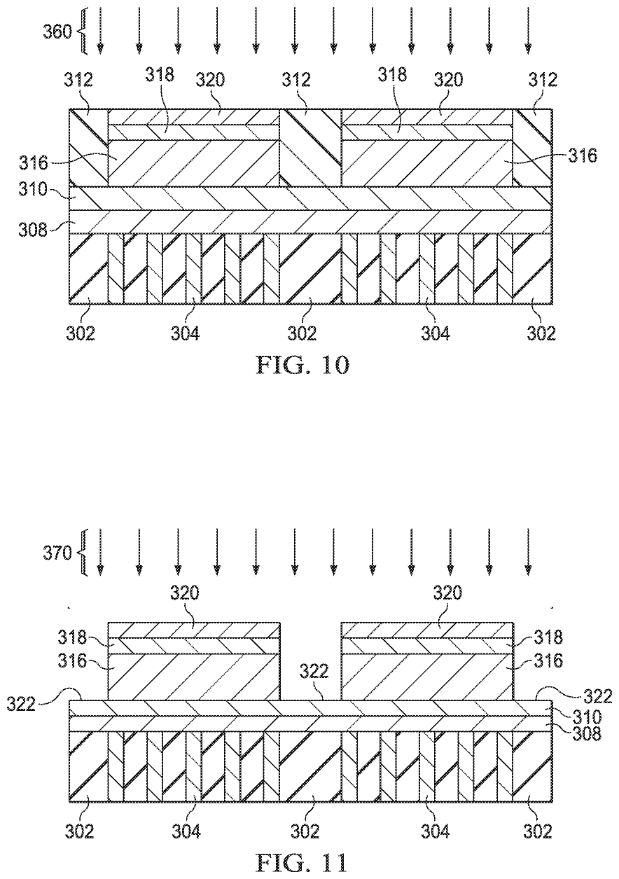

As illustrated in FIG. 8, a mechanical interconnect or bump bond 316 is formed in the openings 314. The bump bond 316 is formed by electroplating a metal (e.g., copper) on the seed layer 310 in the openings 314 of the photoresist material layer 312. A second metal (e.g., nickel) layer 318 is deposited in the openings 314 on the bump bond 316 via electroplating, see FIG. 9. A third metal (e.g., palladium) layer 320 is deposited in the openings 314 via electroplating, see FIG. 10. The remaining photoresist layer 312 is removed via an etching process 360 (FIG. 10) resulting in the configuration illustrated in FIG. 11.

The configuration of the electronic device 300 illustrated in FIG. 11 undergoes an etching process 370 where the electronic device 300 is immersed in a chemical electrolyte (e.g., tin electrolyte) to remove or etch the seed layer 310. The electronic device 300 is immersed in the tin electrolyte for a period of not more than ten minutes. During the immersion, two chemical reactions simultaneously take place.

The first chemical reaction is that exposed portions 322 of the seed layer 310 are dissolved in the chemical electrolyte thereby removing any exposed portions 322 of the seed layer 310. The exposed portions 322 of the seed layer are the portions that are not covered by the bump bonds 316. Since the seed layer 310 is a thin layer of less than 0.5 μm the seed layer 310 completely dissolves in the tin electrolyte.

The second chemical reaction is an exchange reaction between the bump bonds 316 and the tin electrolyte. Specifically, during the second chemical reaction electrons (e.g., copper electrons) are removed from sidewalls 324 of the bump bonds 316. The electrons combine with tin ions in the tin electrolyte to form a thin layer (e.g., 0.2-0.3 μm) of tin 326 on the sidewalls 324 of the bump bonds 316. Thus, the thin layer of tin 326 replaces or is exchanged with a thin layer of the sidewalls 324 of the bump bonds 316. The thin layer of tin 326 inhibits etching to the bump bonds 316 during the seed layer 310 etching process. For an example bump bond 316 comprised of copper, the exchange reaction takes place according to Equations 1 and 2.

Cu−2e→Cu⁺² (1)

Sn⁺²+2e→Sn (2)

The bump bonds 316 do not dissolve in the tin electrolyte like the seed layer 310 because the thickness of the bump bonds 316 is greater than 0.5 μm. In other words, if the thickness of the copper layer is less than 0.5 μm then the copper layer will dissolve in the tin electrolyte because there is no copper to combine with the tin ions. If, however, the thickness of the copper layer is greater than 0.5 μm, approximately 0.5 μm will dissolve in the tin electrolyte and the remaining will combine with the tin ions to form a thin tin layer on the metal layer. After the electronic device 300 is removed from the tin electrolyte, the electronic device is rinsed with water to remove any remaining residue.

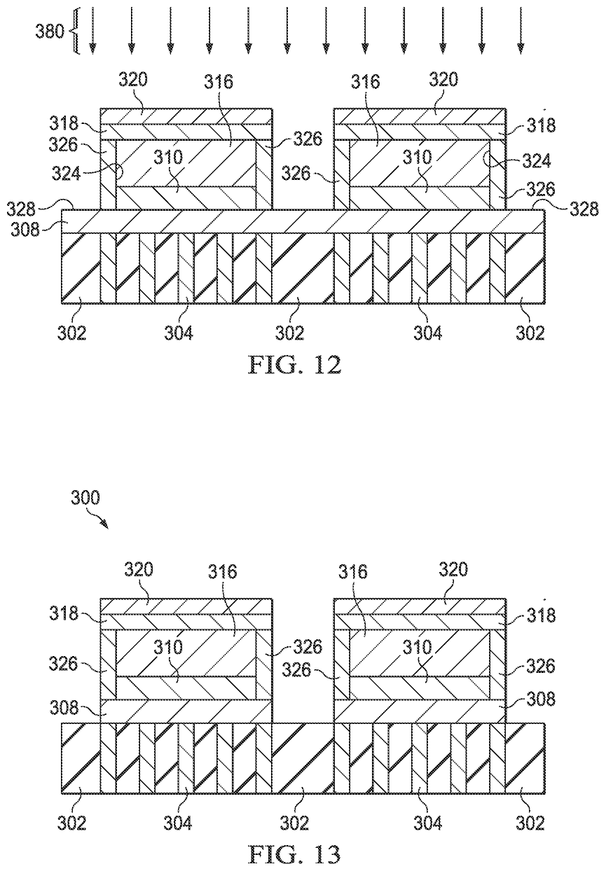

Since the tin electrolyte does not affect the diffusion barrier layer 308, the configuration of the electronic device 300 in FIG. 12 undergoes another etching process (e.g., chemical etching) 380 to remove exposed portions 328 of the diffusion barrier layer 308.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
providing an array of electronic devices comprising a wafer, each of the electronic devices including a copper seed layer disposed on the wafer and at least one copper bump bond disposed on a portion of the copper seed layer; and
immersing the array of electronic devices in a tin electrolyte to chemically dissolve an exposed portion of the copper seed layer in the tin electrolyte and to chemically displace electrons from side walls of the at least one copper bump bond, wherein the displaced electrons combine with tin ions in the tin electrolyte to form a layer of tin on sidewalls of the at least one copper bump bond.

2. The method of claim 1, wherein the array of electronic devices are immersed in the tin electrolyte for a period of no more than ten minutes.

3. The method of claim 1, further comprising rinsing the array of electronic devices with water.

4. The method of claim 1, wherein prior to immersing the array of electronic devices in the tin electrolyte, the method further comprising depositing a diffusion barrier layer on the wafer, depositing the copper seed layer on the diffusion barrier layer, and depositing the at least one copper bump bond on the portion of the seed layer.

5. The method of claim 4, further comprising depositing a photoresist layer on the copper seed layer via spin coating.

6. The method of claim 5, further comprising etching the photoresist layer to form openings in the photoresist layer.

7. The method of claim 6, further comprising depositing copper in the openings on the copper seed layer to form the at least one copper bump bond.

8. The method of claim 7, further comprising depositing a nickel layer in the openings on the at least one copper bump bond.

9. The method of claim 8, further comprising depositing a palladium layer in the openings on the nickel layer.

10. The method of claim 9, further comprising removing the photoresist layer via an etching process.

11. The method of claim 10, further comprising removing an exposed portion of the diffusion barrier layer via an etching process.

12. A method comprising:
providing an array of electronic devices comprising a silicon wafer, each of the electronic devices including a titanium-tungsten diffusion barrier layer disposed on the silicon wafer, a copper seed layer disposed on the titanium-tungsten diffusion barrier layer, and copper bump bonds disposed on a portion of the copper seed layer;
immersing the array of electronic devices for no more than ten minutes in a tin electrolyte to chemically dissolve an exposed portion of the copper seed layer in the tin electrolyte and to chemically displace electrons from side walls of the copper bump bonds, wherein the electrons combine with tin ions in the tin electrolyte to form a layer of tin on sidewalls of the copper bump bonds; and
rinsing the array of electronic devices with water.

13. The method of claim 12, further comprising depositing a photoresist layer on the copper seed layer via spin coating and etching the photoresist layer to form openings in the photoresist layer.

14. The method of claim 13, further comprising depositing copper in the openings on the copper seed layer to form the copper bump bonds.

15. The method of claim 14, further comprising depositing a nickel layer in the openings on the copper bump bonds and depositing a palladium layer in the openings on the nickel layer.

16. The method of claim 15, further comprising removing the photoresist layer via an etching process.

17. The method of claim 16, further comprising removing an exposed portion of the diffusion barrier layer via an etching process.

18. A die comprising:
a silicon wafer;
a diffusion barrier layer disposed on the silicon wafer;
a copper seed layer disposed on the diffusion barrier layer;
at least one copper bump bond disposed on a portion of the copper seed layer; and
a tin layer disposed on side walls of the at least one copper bump bond.

19. The die of claim 18, further comprising a nickel layer disposed on the at least one copper bump bond, and a palladium layer disposed on the nickel layer.

20. The die of claim 18, wherein the diffusion barrier layer is titanium-tungsten.

21. The die of claim 18, wherein the tin layer inhibits etching of the side walls of the at least one copper bump bond during an etching process to the copper seed layer to remove exposed portions of the copper seed layer
